(19) United States
(12) Patent Application Publication
(10) Pub. No.: US 2008/0150126 A1
(43) Pub. Date: Jun. 26, 2008

(54) LIGHT EMITTING DIODE MODULE WITH HEAT DISSIPATION DEVICE

(76) Inventors: ZHI-YONG ZHOU, Shenzhen (CN); Cheng-Tien Lai, Tu-Cheng (TW); Yi-San Liu, Shenzhen (CN)

Correspondence Address: PCE INDUSTRY, INC.;ATT. CHENG-JU CHIANG, 458 E. LAMBERT ROAD, FULLERTON, CA, 92835, US

(21) Appl. No.: 11/615,917

(22) Filed: Dec. 22, 2006

(51) Int. Cl. H01L 23/34

(52) U.S. Cl. 257/712

(57) ABSTRACT

A light emitting diode (LED) module with a heat dissipation device includes a plurality of LEDs supported by the heat dissipation device. The heat dissipation device includes a plurality of heat spreaders each supporting at least one LED, a base supporting the heat spreaders, and a heat pipe sandwiched between the base and the heat spreaders. The heat spreaders are thermally connected together via the heat pipe.

### BACKGROUND OF THE INVENTION

1. Field of the Invention

The present invention relates to a light emitting diode (LED) module, more particularly to an LED module with a heat dissipation device for facilitating heat dissipation.

2. Description of related art

An LED is a device for transforming electricity into light by using the fact that if a current is made to flow in a forward direction in a junction comprising two different semiconductors, electrons and holes will couple in a junction region to generate light. The LED has an advantage in that it is resistant to shock, and has an extremely long operational life, so more and more LED modules with different capabilities are being developed.

LED modules for use in a display or an illumination device require many LEDs, and most of the LEDs are driven at the same time, which results in a quick rise in temperature of the LED module. Since generally the LED modules do not have heat dissipation devices with good heat dissipating efficiencies, operation of the general LED modules suffers from instability because of the rapid build up of heat. Consequently, the light from the LED module often flickers, which degrades the quality of the display or illumination.

What is needed, therefore, is a heat dissipation device for an LED module, which can overcome the above-described disadvantages.

### SUMMARY OF THE INVENTION

A light emitting diode (LED) module with a heat dissipation device is disclosed. The LED module comprises a plurality of LEDs supported on the heat dissipation device. The heat dissipation device comprises a plurality of heat spreaders each supporting at least one LED, a base supporting the heat spreaders, and a heat pipe sandwiched between the base and the heat spreaders. The heat spreaders are thermally connected together via the heat pipe.

Other advantages and novel features will become more apparent from the following detailed description of preferred embodiments when taken in conjunction with the accompanying drawings.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of an LED module in accordance with a preferred embodiment;

FIG. 2 is an exploded view of the LED module in FIG. 1 with a printed circuit board and an LED removed away from an associated heat spreader of the LED module in FIG. 1;

FIG. 3 is similar to FIG. 2, viewed from another aspect showing detailed structures of heat spreaders of the LED module in FIG. 1;

FIG. 4 is an isometric view of an LED module in accordance with another preferred embodiment;

FIG. 5 is a partially exploded view of the LED module in FIG. 4;

FIG. 6 is a top plan view of an LED module in accordance with another preferred embodiment; and

FIG. 7 is an isometric view of an LED module in accordance with another preferred embodiment.

### DETAILED DESCRIPTION OF THE INVENTION

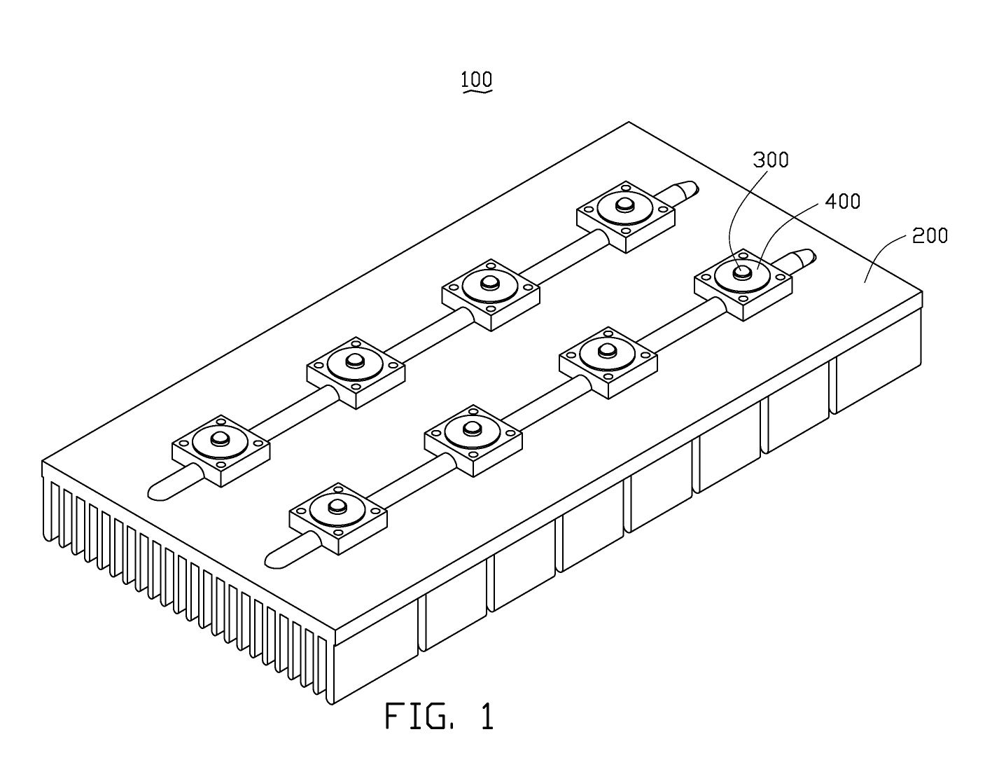

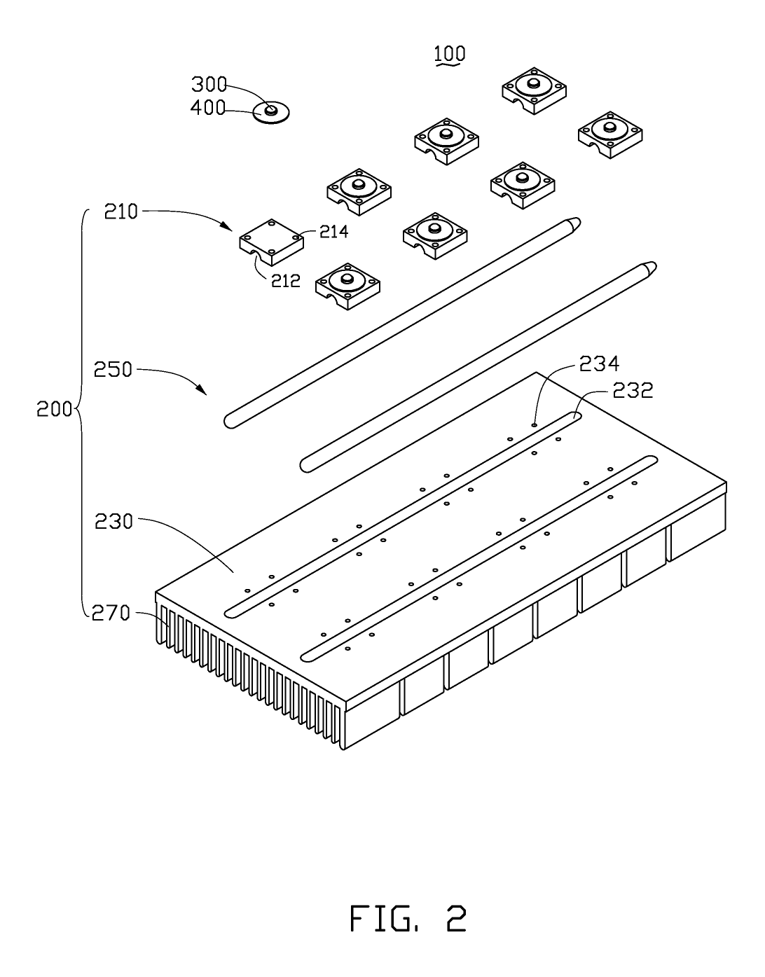

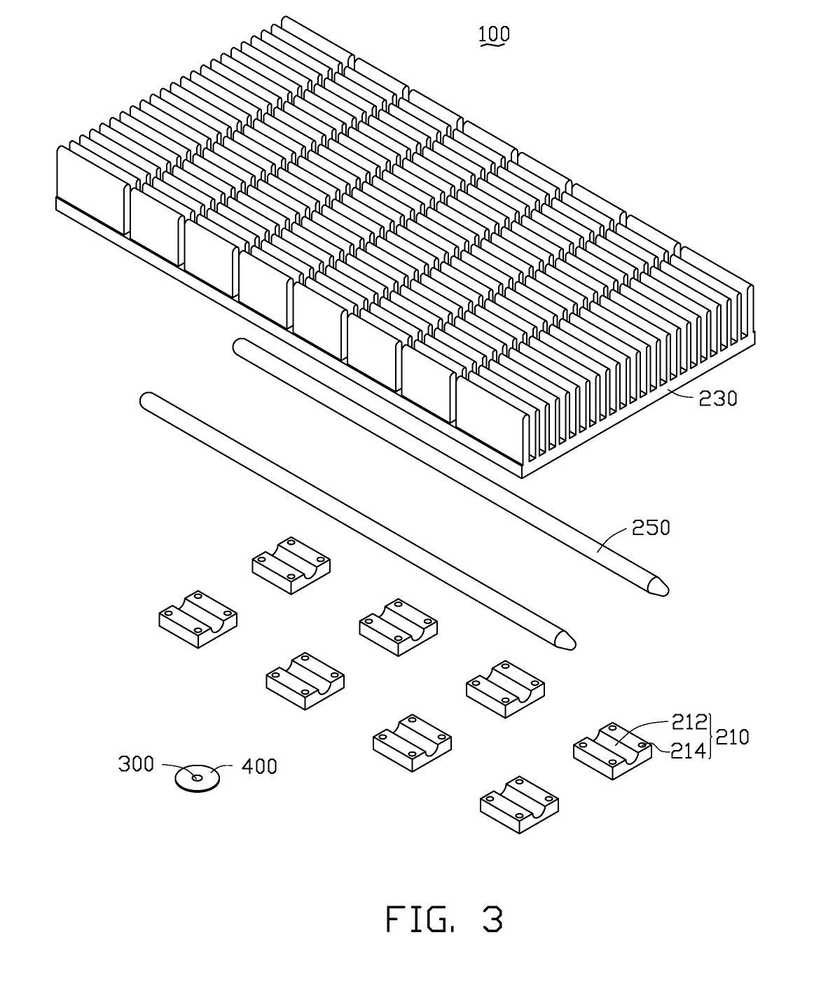

Referring to FIGS. 1-3, an LED module 100 in accordance with a preferred embodiment is illustrated. The LED module 100 can be applied in many different fields, for example, in a display or an illumination device.

The LED module 100 generally comprises a heat dissipation device 200 and a plurality of LEDs 300 each electrically bonded to a circular printed circuit board 400, which is supported on a top surface of the heat dissipation device 200. Each printed circuit board 400 has a through hole (not labeled) defined in a central portion thereof. The LEDs 300 are installed into the corresponding through holes of the printed circuit boards 400, and electrically connected to circuits (not shown) provided on the printed circuit boards 400. The LEDs 300 are then capable of generating light driven and controlled by the printed circuit boards 400.

Before the LEDs 300 are driven to generate light, the heat dissipation device 200 is mounted on bottom surfaces of the printed circuit boards 400, to dissipate heat generated by the LEDs 300.

The heat dissipation device 200 is used to cool down the LEDs 300, to keep the LEDs 300 working within an acceptable temperature range. The heat dissipation device 200 generally comprises a plurality of heat spreaders 210, a base 230 supporting the heat spreaders 210, two straight heat pipes 250 sandwiched between the heat spreaders 210 and the base 230. Moreover, the heat dissipation device 200 further comprises a plurality of fins 270 downwardly and perpendicularly extending from the base 230, to increase the heat dissipating area of the base 230.

The heat spreaders 210 are made of materials with good heat conductivity, and each has a substantially rectangular configuration. The heat spreaders 210 have essentially identical configurations in this embodiment. Alternatively, some parameters of the heat spreaders 210, for example, the dimensions or size, can be adjusted to give the heat spreaders 210 similar or different configurations. In the following text, the detailed structure of the heat spreaders 210 will be described.

Each heat spreader 210 comprises a flat top portion and a bottom portion opposite to the top portion. The flat top portion directly contacts with one associated LED 300 supported on an associated printed circuit board 400, and absorbs heat therefrom. In the bottom portion of the heat spreader 210, a straight groove 212 is defined near a middle portion thereof. The groove 212 extends through opposite ends of the heat spreader 210, for fittingly receiving a top part of one heat pipe 250 therein. Each groove 212 has a curved surface matching with a top surface of the heat pipe 250; thus, the heat pipe 250 can be fittingly received in the groove 212 of the heat spreader 210 and has an intimate contact with the heat spreader 210.

The heat spreader 210 further has four through holes 214 defined in corners thereof. The through holes 214 surround the associated printed circuit board 400, for screws (not shown) extending therethrough to secure the heat spreader 210 to the base 230 of the heat dissipation device 200.

The base 230 is positioned under the heat spreaders 210. Two parallel straight grooves 232 are defined in a top portion of the base 230 for receiving the heat pipes 250 therein. A plurality of threaded holes 234 is defined in opposite sides of each straight groove 232 of the base 230. The threaded holes 234 of the base 230 are arranged at a predetermined interval so that the threaded holes 234 are capable of aligning with the through holes 214 of the associated heat spreaders 210.

When assembling the heat spreaders 210 to the base 230, the two heat pipes 250 are first installed into the corresponding grooves 232 of the base 230. Then, the heat spreaders 210 are positioned on the top surface of the base 230 with the grooves 212 thereof aligning with the corresponding grooves 232 of the base 230. As a result, the heat spreaders 210 span across the associated heat pipes 250 and are arrayed to form two lines and four rows at a predetermined interval. Thus, the heat spreaders 210 are thermally connected in series via the heat pipes 250 along the grooves 232 of the base 230. Finally, the screws are pushed to extend through the through holes 212 of the heat spreaders 210 to threadedly engage with the corresponding threaded holes 234 of the base 230. Therefore, the heat spreaders 210 are secured on the base 230.

When one LED 300 needs to be repaired or replaced, the screws can be unscrewed from the base 210. This facilitates and simplifies the process of repairing the LED module 100.

After the heat spreaders 210 are secured on the base 230, each heat pipe 250 thermally connects four spaced heat spreaders 210 in series. The sections of each heat pipe 250 extending in the associated heat spreaders 210 serves as evaporators for the heat pipe 250 to absorb the heat accumulated at the heat spreaders 210. Accordingly, the sections of each heat pipe 250 extending between two neighboring heat spreaders 210 serves as condensers for the heat pipe 250, to dissipate the heat absorbed by the evaporators of the heat pipe 250.

Since the heat spreaders 210 with the LEDs 300 span across the heat pipes 250 at intervals, each heat pipe 250 has a plurality of evaporators and a plurality of condensers distributed in alternating fashion. In other words, each single condenser of one heat pipe 250 is positioned between two adjacent evaporators. This helps to make good use of every section of the heat pipes 250 to dissipate heat. The heat originating from the LEDs 300 can be quickly spread at the whole base 230 via the heat pipes 250. As a result, the LED module 100 can work within an acceptable temperature range; the operation of the LED module 100 is stable. Consequently, the quality of the display or illumination of the LED module 100 is improved.

As described above, the heat spreaders 210 arranged in a line are connected in series via two straight heat pipes 250. However, the heat spreaders 210 can also be thermally connected via one or more straight heat pipes 250. For another embodiment, the heat spreaders 210 can also be thermally connected via U-shaped heat pipes, S-shaped heat pipes, V-shaped heat pipes, or any other shaped heat pipes, or combination of different shaped heat pipes.

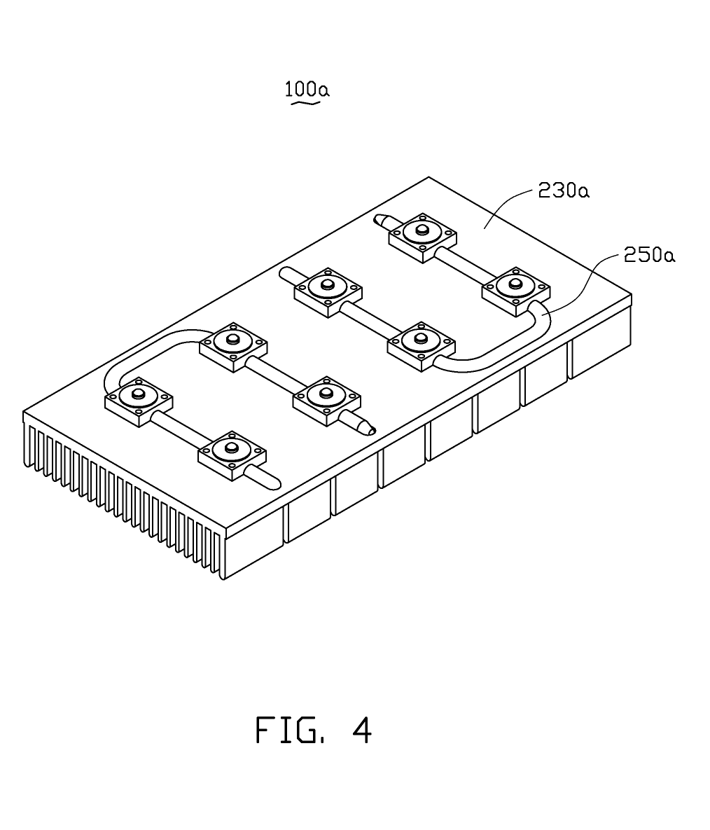

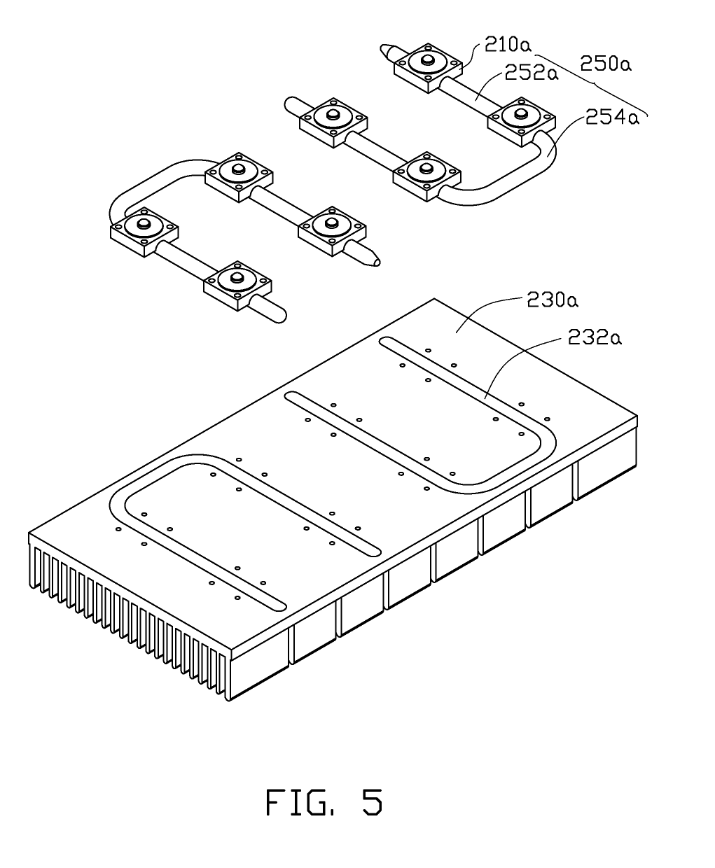

For example, FIGS. 4-5 show an LED module 100a incorporated with two U-shaped heat pipes 250a in accordance with another preferred embodiment of the present invention. The main difference between this preferred embodiment and the previously described preferred embodiment is that the heat pipes 250a each have a U-shaped configuration, and the base 230a defines two juxtaposed U-shaped grooves 232a for receiving the corresponding U-shaped heat pipes 250a. Each U-shaped heat pipe 250a has two parallel arms 252a and a connecting portion 254a connecting the two arms 252a together.

As shown in FIG. 4, the two heat pipes 250a are juxtaposed in the corresponding grooves 232a of the base 230a in such a manner that each arm 252a of each heat pipes 250a thermally connects two spaced heat spreaders 210a in series, and the connecting portions 254a of the heat pipes 250a are located at opposite sides of the base 230a. The sections of the heat pipes 250a contact with the heat spreaders 210a serve as evaporators for the heat pipes 250a, while other sections of the heat pipes 250a serve as condensers for the heat pipes 250a. Thus, in this embodiment, each single evaporator of each heat pipe 250a is positioned between two adjacent condensers.

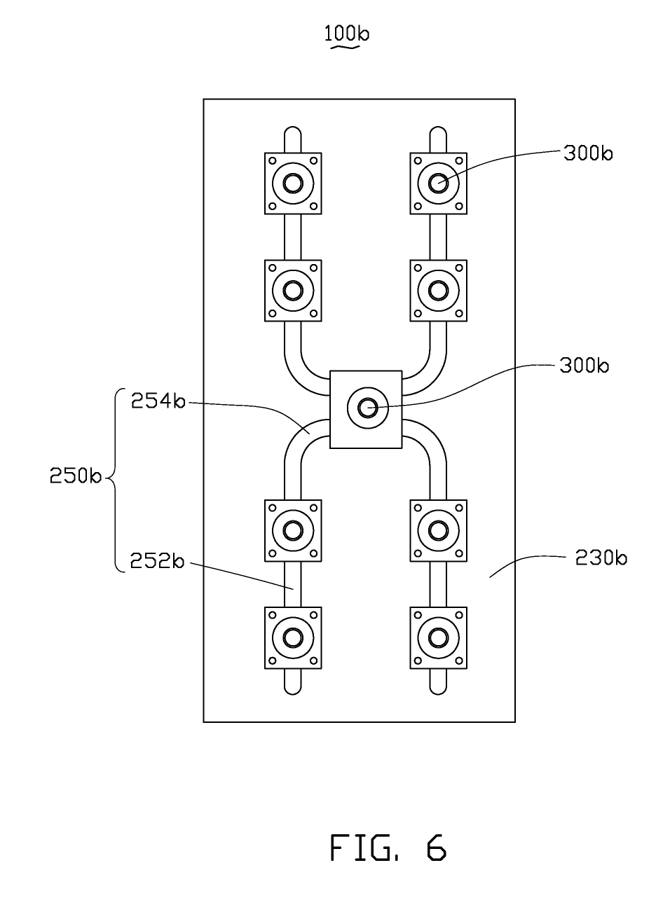

FIG. 6 shows an LED module 100b in accordance with another preferred embodiment of the present invention. This embodiment is similar to the LED module 100a shown in FIGS. 4-5. This LED module 100b comprises a plurality of LEDs 300b with different powers; more particularly, an LED 300b positioned in a central portion of the base 230b has a higher power than the other LEDs 300b. The LED 300b in the central portion of the base 230b functions as a main lamp for the LED module 100b, while the other LEDs 300b function as auxiliary lamps for the LED module 100b.

During operation, the main lamp will generally produce more waste heat needing to be dissipated than the axuxiliary lamps. The main lamp needs a heat dissipating structure with a higher heat dissipating efficiency compared to the auxiliary lamps.

To quickly dissipate the heat originating from the LEDs 300b, the two U-shaped heat pipes 250b of this preferred embodiment are arranged in the base 230b in such a manner that they open in opposite directions with the connecting portions 254b of them close to or even abutting against each other in a central portion of the base 230b, where the main lamp is located. Each arm 252b of each heat pipe 250b connects two auxiliary lamps in a similar manner as described above in connection with the second embodiment. By such arrangement, the main lamp directly contacts with the two connecting portions 254b of the heat pipes 250b, simultaneously. This helps to accelerate the heat dissipation of the main lamp to keep the main lamp working within a normal temperature range. Thus, the quality of the display or illumination of the LED module 100b is improved.

The previous text has described several preferred embodiments of the present invention. In these embodiments, when the LEDs 300 (300a, 300b) are driven to luminance, the heat produced by the LEDs 300 (300a, 300b) is first spread at the base 230 (230a, 230b) via the heat spreaders 210 (210a, 210b) and the heat pipes 250 (250a, 250b), then is dissipated to ambient air via the fins formed on the base 230 (230a, 230b).

For facilitating heat dissipation of the LEDs 300 (300a, 300b), bottom surfaces of the LEDs 300 (300a, 300b) commonly define a surface coplanar with a bottom surface commonly defined by the printed circuit boards 400, or located in a level below the bottom surface of the printed circuit boards 400. By such design, the LEDs 300 (300a, 300b) can directly contact the heat spreaders 210 (210a, 210b), and this serves to accelerate heat dissipation.

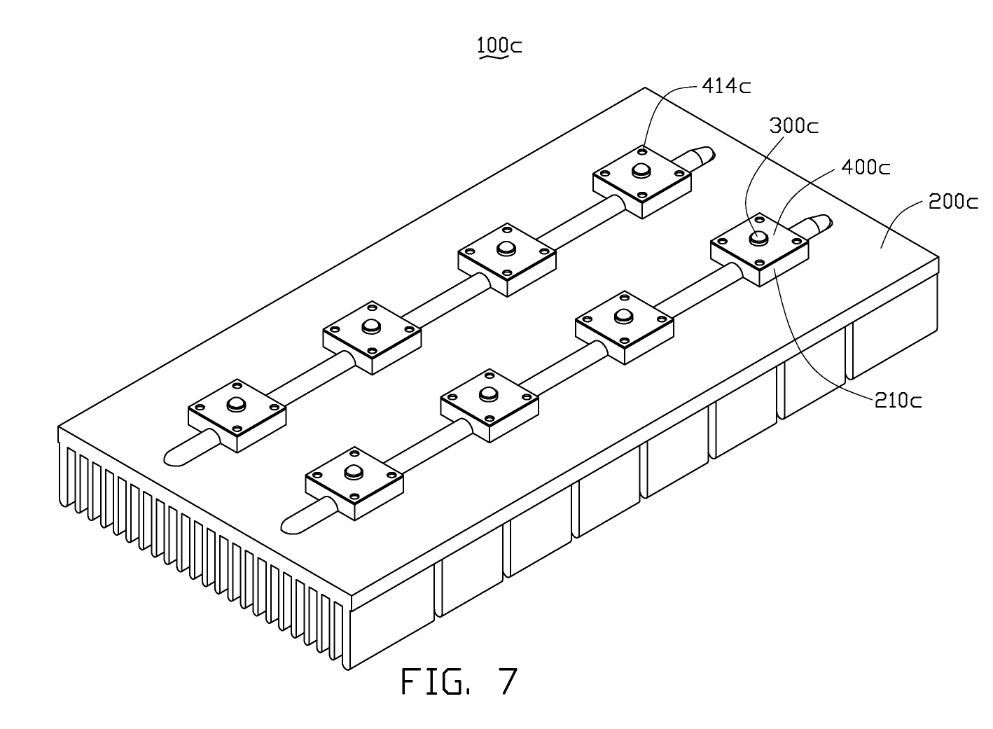

Additionally, the printed circuit boards 400 with the LEDs 300 (300a, 300b) may be attached to the heat spreaders 210 (210a, 210b) via glue or other conventional method. Alternatively, for further facilitating assembling or repairing the LED module, the printed circuit board may be mounted on the heat spreader via screws (not shown). An example is shown in FIG. 7. The printed circuit board 400c has a configuration and a size the same as the heat spreaders 210c. Each printed circuit board 400c defines four through holes 414c in corners thereof corresponding to the through holes (not shown) of the heat spreaders 210c.

When assembling the printed circuit boards 400c and the heat spreaders 210c, the screws (not shown) are pushed to extend through the associated through holes 414c of the printed circuit boards 400c and the associated through holes of the heat spreaders 210c in turns, then are threaded into the threaded holes of the base of the heat dissipation device 200c. Thus, the LED module 100c is assembled. When there is a need to disassemble one printed circuit board 400c from the LED module 100c, just unscrew the associated screws from the LED module 100c. The printed circuit board 400c together with the LED 300c is then easily removed away from the LED module 100c. Thus, the LED module 100c has a high versatility for general use.

Additionally, in FIGS. 1-5, 7, there are only eight LEDs shown on the top surface of the heat dissipation device. However, the number of the LEDs to be mounted on the heat dissipation device is a choice of design matter. The number of the LEDs can be predetermined or adjustable according to the requirements of applications in different situations.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A light emitting diode (LED) module with a heat dissipation device comprising:
a plurality of LEDs supported on the heat dissipation device;
a plurality of heat spreaders each supporting at least one of the LEDs;
a base supporting the heat spreaders; and
a heat pipe sandwiched between the base and the heat spreaders, wherein the heat spreaders are thermally connected together via the heat pipe.

2. The LED module as claimed in claim 1, wherein said each heat spreader has a groove defined therein, for receiving a part of the heat pipe.

3. The LED module as claimed in claim 2, wherein the base defines a groove for receiving the heat pipe, and after the heat pipe is installed in the groove of the base, the heat spreaders span across on the heat pipe with the grooves of the heat spreaders receiving parts of the heat pipe.

4. The LED module as claimed in claim 3, wherein said each heat spreader defines a plurality of through holes in corners thereof, for screws extending therethrough to secure the heat spreaders on the base.

5. The LED module as claimed in claim 4, wherein the base defines a plurality of threaded holes in each side of the groove of the base, the threaded holes aligning with associated through holes of the heat spreaders so that the screws are capable of extending through the through holes of the heat spreaders to engage into the threaded holes of the base.

6. The LED module as claimed in claim 5, further comprising a plurality of printed circuit boards each supported by an associated heat spreader, wherein the LED mounted on said each heat spreader is connected electrically to the printed circuit board supported by said each heat spreader.

7. The LED module as claimed in claim 6, wherein the printed circuit board supported on said each heat spreader is surrounded by the through holes of said each heat spreader.

8. The LED module as claimed in claim 6, wherein the printed circuit board supported on said each heat spreader defines a plurality of through holes corresponding to the through holes of said each heat spreader, so that the screws are capable of extending through the through holes of the printed circuit board supported on said each heat spreader and said each heat spreader to engage into the threaded holes of the base.

9. The LED module as claimed in claim 3, wherein the heat spreaders are thermally connected in series via the heat pipe along the groove of the base.

10. The LED module as claimed in claim 9, wherein the neighboring heat spreaders are spaced from each other by a section of the heat pipe, which serves as a condenser of the heat pipe.

11. A light emitting diode (LED) module, comprising:
a plurality of printed circuit boards each having an LED electrically bonded thereto; and
a heat dissipation device comprising:
a plurality of heat spreaders each supporting an associated printed circuit board thereon and directly contacting with the LED mounted on the associated printed circuit board;
a base supporting the heat spreaders;
two heat pipes sandwiched between the base and the heat spreaders, wherein some of the heat spreaders are thermally connected together via one of the heat pipes, and the other of the heat spreaders are thermally connected together via the other heat pipe.

12. The LED module as claimed in claim 1, wherein the heat pipes are straight, and the heat pipes thermally connect the heat spreaders in series along two lines.

13. The LED module as claimed in claim 1, wherein the heat pipes each has a U-shaped configuration, and each heat pipe comprises two arms and a connecting portion connecting the two arms, each arms of the heat pipe contacting with at least one heat spreader.

14. The LED module as claimed in claim 13, wherein the two heat pipes open towards different directions.

15. The LED module as claimed in claim 14, wherein the heat pipes open to opposite directions in such a manner that the connecting portions of the heat pipes locate at opposite sides of the base.

16. The LED module as claimed in claim 14, wherein the heat pipes open to opposite directions in such a manner that the connecting portions of the heat pipes close to each other in a central portion of the base.

17. The LED module as claimed in claim 16, wherein the connecting portions of the heat pipes thermally contact with a same LED via one heat spreader.
